(19) United States
(12) Patent Application Publication
(10) Pub. No.: US 2025/0372576 A1
(43) Pub. Date: Dec. 4, 2025

(54) SEMICONDUCTOR DEVICE PACKAGE WITH STUB LEADS AND METHODS

(71) Applicant: Texas Instruments Incorporated, Dallas, TX (US)

(72) Inventors: Han Meng Lee, Cheras (MY); Anis Fauzi Bin Abdul Aziz, Melaka (MY); You Chye How, Melaka (MY)

(21) Appl. No.: 18/679,050

(22) Filed: May 30, 2024

(51) Int. Cl. H01L 23/00; H01L 21/56; H01L 23/31; H01L 23/495

(52) U.S. Cl. CPC H01L 24/96; H01L 21/561; H01L 23/3107; H01L 23/49541; H01L 24/16; H01L 24/48; H01L 24/81; H01L 24/85; H01L 2224/16245; H01L 2224/48175; H01L 2224/81; H01L 2224/85; H01L 2224/96

(57) ABSTRACT

In a described example, a semiconductor device package includes: a semiconductor die mounted to a device side surface of a device unit of a package substrate, the device unit having leads extending from a die mount area; electrical connections between bond pads on the semiconductor die and the leads of the device unit; and mold compound covering the semiconductor die, the electrical connections, and portions of the leads, the mold compound forming the body of a semiconductor device package for the semiconductor die having a board side surface, and opposing top side surface, and sides between the board side surface and the top side surface; wherein the leads extend outwards on two opposite sides from the body of the semiconductor device package formed by the mold compound and the leads have a board side surface that is coplanar with the board side surface of the mold compound.

### TECHNICAL FIELD

This disclosure relates generally to semiconductor device packages, and more particularly to a method for fabrication of a semiconductor device package with a molded package body.

### BACKGROUND

Semiconductor dies are produced for use in electronic circuits using semiconductor wafer manufacturing facilities (sometimes referred to as “wafer fabs”) to form semiconductor dies on a device side surface of a semiconductor wafer. Example semiconductor wafer materials include silicon, germanium, gallium arsenide, gallium nitride, sapphire, silicon carbide and indium phosphide, with silicon being the most used semiconductor wafer material. Example wafer fabrication processes for making semiconductor dies include ion implantation, thermal anneals, thermal oxidation, chemical vapor deposition, dielectric deposition, conductor deposition, sputtering, damascene deposition, chemical mechanical polishing, and passivation layer deposition.

Once the semiconductor dies are complete, the individual devices are removed from the semiconductor wafer by a process referred to as “singulation.” In semiconductor die singulation, the semiconductor wafer is separated into individual semiconductor dies by “wafer dicing.” In one approach, a mechanical saw is used. A rotating saw blade moves along scribe lanes formed between the semiconductor dies and cuts through the semiconductor wafer in multiple passes. During wafer dicing the semiconductor wafer is supported by a removable film or tape, a backside or dicing tape, which supports the dies as the scribe lanes are cut through. Alternative dicing processes include laser dicing and plasma dicing. The semiconductor dies can be square or rectangular in shape. Tens, hundreds or even thousands of semiconductor dies can be formed on a single semiconductor wafer. The scribe lanes are defined areas on the semiconductor wafer between the dies that are parallel to one another in two directions, so that each semiconductor die has four vertical sides after the wafer dicing, the vertical sides extend from a device side surface to a backside surface, so that an individual semiconductor die has six sides, and is a cube.

After the semiconductor wafer is diced into individual semiconductor dies, the individual semiconductor dies can be mounted to a package substrate and a semiconductor device package is formed. In an example process, the individual semiconductor dies are mounted to a die pad, with bond pads on the semiconductor dies facing away from the die pad. A die attach film can be used to attach the semiconductor die to the die pad. Electrical connections are formed between the semiconductor die and leads of the package substrate, for example wire bonds can be formed to couple bond pads on the semiconductor die to the leads of the package substrate. After the electrical connections are formed, a package body can be formed using a mold compound. For example, a transfer molding process can be used to cover the semiconductor die, the electrical connections, and portions of the package substrate with the mold compound, while portions of leads are left exposed from the mold compound to form device terminals for the semiconductor device package.

Currently, and particularly for low pin count semiconductor dies, two package types are increasingly used. Small outline integrated circuit (“SOIC”) semiconductor devices packages are leaded packages with leads extending from the molded package body on at least two sides, for SOIC packages the leads can have a “gull wing” shape. The SOIC packages are well accepted and widely used, many existing system board and module designs have conductive lands patterned to receive the SOIC packages, and the SOIC packages have excellent board level reliability (“BLR”), in part because the gull wing shaped leads can move slightly without breaking the solder joints to the board. In production of the SOIC devices, the spacing needed between the devices on a package substrate strip (for example a leadframe strip) requires an area that cannot be used for additional semiconductor die devices, reducing yield.

Increasingly, as an alternative package type, quad flat no-lead (“QFN”) semiconductor device packages are used. QFN semiconductor device packages have terminals that are coextensive with a molded package body, and thus take less area on a board or module when mounted to it (when compared to leaded packages including SOIC packages). The QFN terminals are exposed for solder surface mount on the board side of the semiconductor device package. However, QFN packages have lower BLR than corresponding SOIC packages.

The molding process used to form the semiconductor device packages can be performed using unit molding or block molding. In unit molding, a mold has a shaped cavity portion that surrounds each of the semiconductor dies mounted to a package substrate strip in an array or grid pattern. In block molding, columns of devices are placed in a mold that surrounds the column of devices, and each column is molded in a block. After molding, the semiconductor device packages are cut apart from one another by a mechanical sawing process that cuts through the package substrate material and through any mold compound that remains in saw streets between the finished semiconductor device packages. For conventional leaded packages, additional steps to shape, trim and form the leads are required for each packaged device in a “trim and form” process. In some packages the leads are formed to a “gull wing” shape, which requires the leads to have a length sufficient to be shaped first extending from the middle of the body of the semiconductor package, then slanting downwards at an angle to “feet” portions that extend away from the semiconductor package. Gull wing leads are arranged for surface mounting to a conductive land pattern formed on a system board, circuit board or module using solder.

Improvements are needed for producing reliable and robust semiconductor device packages using molding to increase the number of units per strip, and to simplify the processes to reduce device costs.

### SUMMARY

In a described example, a method includes: mounting semiconductor dies on die mount areas of device units of a package substrate strip, the device units being arranged in columns along at least one row and spaced from one another by saw streets between the columns, the device units having leads arranged with ends proximate to the die mount areas and extending to the saw streets. Electrical connections are formed between bond pads on the semiconductor dies and leads of the device units of the package substrate. Mold compound is formed over the semiconductor dies, the electrical connections, and portions of the leads, the mold compound forming a continuous panel of mold compound covering the device side of the package substrate strip. In a first sawing operation, the mold compound is cut in the saw streets between columns of the device units, exposing a top surface of the leads between the semiconductor dies, the sawing operation forming vertical sides of packaged semiconductor devices for each column of the device units, the leads extending from the vertical sides of the semiconductor device packages. In a second sawing operation, a saw cuts through the package substrate and any mold compound along saw streets between the device units to separate semiconductor device packages formed on the package substrate device units from one from another; wherein the semiconductor device packages have leads extending from two opposite sides of the mold compound for the semiconductor device packages, the leads having a board side surface that is coplanar with the board side surface of the semiconductor device packages, the leads having mold compound between the leads on opposing side surfaces of the leads.

In another described example, another method of forming a semiconductor device package includes: forming a strip of device units of a package substrate with a device side surface and an opposite board side surface, the strip comprising an array of device units arranged in columns along at least one row, the device units having leads on two sides extending from and coupled between the columns in saw streets between the columns, and having die pads in a die mount area spaced from internal ends of the leads. Semiconductor dies are mounted to the die pads of the device units, the semiconductor dies having bond pads and mounted with the bond pads facing away from the device side surface of the device units. Wire bonds are formed between the bond pads of the semiconductor dies and leads of the device units. Mold compound is formed covering the device side surface of the package substrate strip in a continuous block of mold compound, the leads having a board side surface exposed from the mold compound. In a first sawing operation, openings are formed into the mold compound in the saw streets between the columns of device units to expose a top side surface of the leads, the first sawing operation forming opposing vertical sides of semiconductor device packages for each semiconductor die. In a second sawing operation, the layer of mold compound and the package substrate strip are cut through along the saw streets between the columns and sawing is performed along additional saw streets between rows of the device units to separate the semiconductor device packages from one another, the second sawing operation forming vertical sides at opposing ends of the semiconductor device packages, and the semiconductor device packages having leads extending on two opposite sides, the leads having a board side surface that is coplanar with the board side surface of the semiconductor device package.

In another described example, a semiconductor device package includes a semiconductor die mounted to a device side surface of a device unit of a package substrate, the device unit having leads extending from a die mount area; electrical connections between bond pads on the semiconductor die and the leads of the device unit. Mold compound covers the semiconductor die, the electrical connections, and portions of the leads, the mold compound forming the body of a semiconductor device package for the semiconductor die having a board side surface, and opposing top side surface, and vertical sides between the board side surface and the top side surface. The leads extend outwards on two opposite sides from the body of the semiconductor device package formed by the mold compound and the leads have a board side surface that is coplanar with the board side surface of the mold compound.

### BRIEF DESCRIPTION OF THE DRAWINGS

FIGS. 1A-B illustrate, in projection views, a semiconductor wafer and a semiconductor die, respectively, the semiconductor die arranged for wire bonding. FIGS. 1C-1D illustrate, in additional projection views, another semiconductor wafer and another semiconductor die, respectively, the another semiconductor die from the another semiconductor wafer arranged for flip chip mounting.

FIGS. 2A-2C illustrate, in a plan view from a top side, an end view, and a side view, respectively, a semiconductor device package that can be used with an arrangement.

FIGS. 3A-3C illustrate, in a plan view from a top side, an end view, and a side view, respectively, another semiconductor device package that can be used with an alternative arrangement.

FIGS. 4A-4B illustrate, in cross-sectional views of two arrangements, an example semiconductor device package with wire bonds, and an example semiconductor device package with flip chip mounting, respectively.

FIGS. 5A-5B illustrate, in plan views, a package substrate strip for use in an arrangement, and the package substrate strip after a molding process, respectively.

FIGS. 6A-6G illustrate, in a series of views, selected steps used to form a semiconductor device package of the arrangements. FIGS. 6H and 6I illustrate, in two projection views, a first semiconductor device package of an example arrangement, and a second semiconductor device package of a further example arrangement, respectively, that can be formed using the steps shown in FIGS. 6A-6G.

FIGS. 7A-7C illustrate, in plan views, a land pattern for an small outline semiconductor device package, a first example arrangement shown overlying the land pattern to illustrate compatibility of the arrangement with the land pattern, and a second example arrangement overlying the land pattern to illustrate compatibility of an alternative arrangement with the land pattern, respectively.

FIG. 8 is a flow diagram illustrating steps of a method for forming an arrangement.

### DETAILED DESCRIPTION

Corresponding numerals and symbols in the different figures generally refer to corresponding parts, unless otherwise indicated. The figures are not necessarily drawn to scale.

The term “scribe lane” is used herein. A scribe lane is a portion of semiconductor wafer between semiconductor dies. Sometimes in related literature the term “scribe street” is used. Once processing is finished and the semiconductor devices are complete, the semiconductor devices are separated into individual semiconductor dies by severing the semiconductor wafer along the scribe lanes. The separated dies can then be removed and handled individually for further processing including packaging. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “package substrate” is used herein. A package substrate is a substrate that includes conductive leads arranged to be coupled to a semiconductor die in a semiconductor device package, and to support the semiconductor die. Examples of package substrates useful with the arrangements include leadframes, pre-molded leadframes (“PMLF”), molded interconnect substrates (“MIS”), partially etched or half-etched leadframes, and multilayer substrates including additive build-up substrates such as substrates formed with Ajinomoto Build-Up Film (“ABF”) that is commercially available from the Ajinomoto Co. Inc., in Tokyo Japan, and other laminated substrates. In the description, a package substrate is provided with a strip of device units, each device unit is arranged to provide leads and support for a semiconductor die to be packaged as a semiconductor device package. Note that while a device unit can be a portion of a leadframe, the “frame” portion of a leadframe is removed during packaging to free the individual leads from one another, so to avoid any misinterpretation or confusion, the term “device unit” is used herein for a single unit of a package substrate strip, the device unit includes leads and supports the semiconductor die during packaging and in the semiconductor device package. The package substrate strip can be a leadframe strip but can also be a molded interconnect substrate strip, a routable leadframe strip, or other substrate used for packaging semiconductor devices.

The term “saw street” is used herein. Saw streets are areas between the semiconductor device packages on a package substrate that provide areas for sawing between the semiconductor device packages.

Elements are described herein as “coupled.” As used herein, the term “coupled” includes elements that are directly connected, and elements that are electrically connected even with intervening elements or wires are also coupled.

The term “semiconductor die” is used herein. A semiconductor die can be a discrete semiconductor device such as a bipolar transistor, a few discrete devices such as a pair of power field effect transistor (FET) switches fabricated together on a single semiconductor die, or an integrated circuit with multiple semiconductor devices in a circuit such as the multiple capacitors in an A/D converter. The semiconductor die can include passive devices such as resistors, inductors, filters, or active devices such as transistors. The semiconductor die can be an integrated circuit with hundreds or thousands of transistors coupled to form a functional circuit, for example a microprocessor or memory semiconductor device. The semiconductor die can be a passive device such as a sensor, example sensors include photocells, transducers, and charge coupled devices (CCDs), or can be a micromechanical device, such as a digital micromirror device (DMD) or a MEMS device.

The term “plasma dicing” is used. In plasma dicing, a semiconductor wafer is diced using a plasma chamber and performing a plasma etch process. In plasma dicing, a mask is applied over the device side surface of a semiconductor wafer. The mask is patterned to expose the scribe lanes. An isotropic etch is formed using a gas in the plasma chamber in the first step of a Bosch cycle. During the Bosch cycle, an etch is performed to a certain depth, then a deposition of a protective material is performed in the plasma chamber, followed by another etch to remove the protective material from the bottom of the trench, and then an additional etch is performed to deepen the trench. By repeating the etch cycle multiple times, highly isotropic etches can be performed and the semiconductor wafer can be etched completely through in the scribe lanes.

The term “dicing die attach film” is used herein. In the arrangements, a dicing die attach film is a combination of a die attach film and a dicing tape, laminated together. By laminating these materials together prior to mounting them to a semiconductor wafer, certain steps in providing these materials on the backside of a semiconductor wafer are simplified, lowering assembly costs.

In the arrangements, a novel package type is formed, and a novel molding process is used to increase the number of units per strip (UPS), and to reduce or eliminate the trim and form steps used for conventional leaded packages. In the arrangements. the novel semiconductor device packages have “stub” leads, the term “stub lead” as used herein means a lead of a semiconductor device package that extends outward from and has a surface coplanar with the board side surface of the semiconductor device package, with the entire board side surface of the stub lead available for solder wetting in a surface mounting technology (SMT) process. The stub lead packages have board level reliability (BLR) that is increased when compared to conventional QFN packages, where the QFN device leads form terminals that do not extend from the molded package body and have less area for solder wetting than the stub lead semiconductor device packages in the arrangements. The stub lead semiconductor device packages of the arrangements can be formed to be compatible with existing SOIC package land patterns on boards and modules, so that changes to existing board designs are not needed to implement and use the stub lead semiconductor device packages of the arrangements. In alternative arrangements, the stub lead semiconductor device packages can have footprints that are new patterns, useful for new board designs, to reduce board area and increase the number of units per strip still further.

In an example process to mold the stub lead semiconductor device packages, and in sharp contrast to prior methods for molding conventional SOIC or QFN semiconductor device packages, a panel mold process is used. In this method, the entire array of semiconductor dies and corresponding units on a package substrate array or strip is molded to form one solid panel of mold compound. The use of a single panel of mold compound results in a mold chase that allows semiconductor devices of different size and pinouts to be molded in the same mold tool, reducing tooling costs and eliminating the need to design new molds or change molds for new or modified semiconductor device packages. The panel of mold compound formed in the novel process covers the stub leads, the semiconductor dies, the wire bonds or flip chip mounts, the device units of the package substrate strip or array, and the saw streets between the rows and columns of device units of the molded devices. A first pass by a dicing saw cuts into the mold compound from the top side surface and cuts along the sides of the molded devices along the saw streets for the columns, defining two of the sides of the semiconductor device packages and exposing the top side surface of the stub leads extending away from the semiconductor device packages. At this point in the example process, an optional post mold plating can be performed to plate the leads while the unit strip is still intact and supports the devices. After the optional post mold plating, a second pass by a dicing saw cuts through the lead material in saw streets along the columns where the stub leads are joined along the saw streets between devices, and in additional passes cuts through the mold compound and the package substrate strip along saw streets between the adjacent ends of the semiconductor device packages, completing the singulation of the semiconductor device packages. Because the stub leads extend outwards a relatively short distance from the package body (compared to prior leaded packages such as SOIC or SOP) and are coplanar with the bottom of the semiconductor device package, and in contrast to SOIC leads which extend from a centerline of the molded packages and because the stub leads are not “gull wing” shaped, the previous lead finishing steps of “trim and form” are not required with the novel stub lead semiconductor device packages, reducing costs, reducing tooling needed, and increasing throughput. The stub lead semiconductor device packages of the arrangements are complete after singulation, without the need for additional lead processing. An advantage attained by use of the stub lead semiconductor device packages of the arrangements is that the number of units produced from a strip (UPS) is substantially increased (when compared to the number of SOIC packages formed by molding a package substrate strip), this is true even if a high density interdigitated lead package substrate strip is used for the SOIC packages. The stub lead device units require less area between devices on the package substrate strip, and thus enable more devices per strip to be packaged simultaneously.

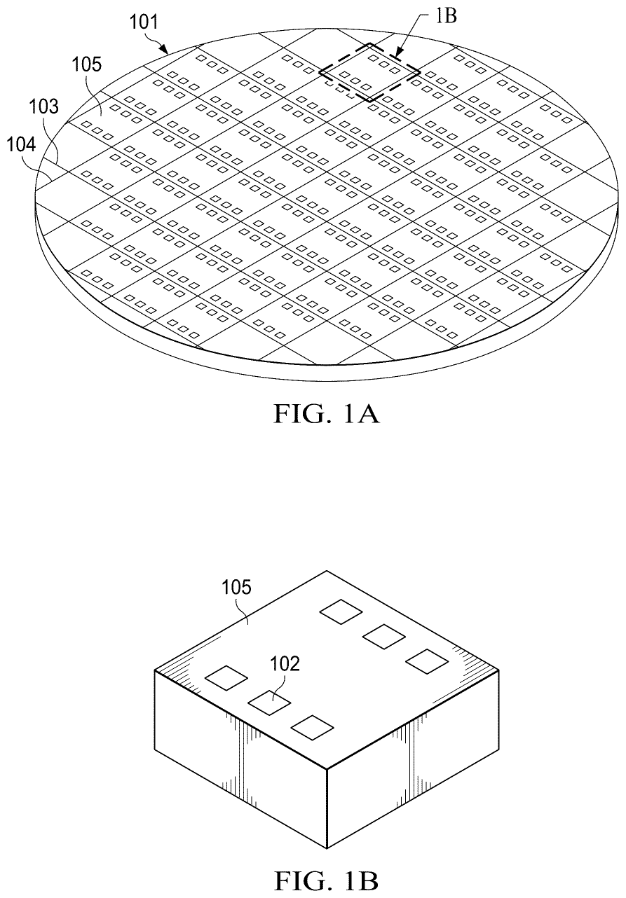

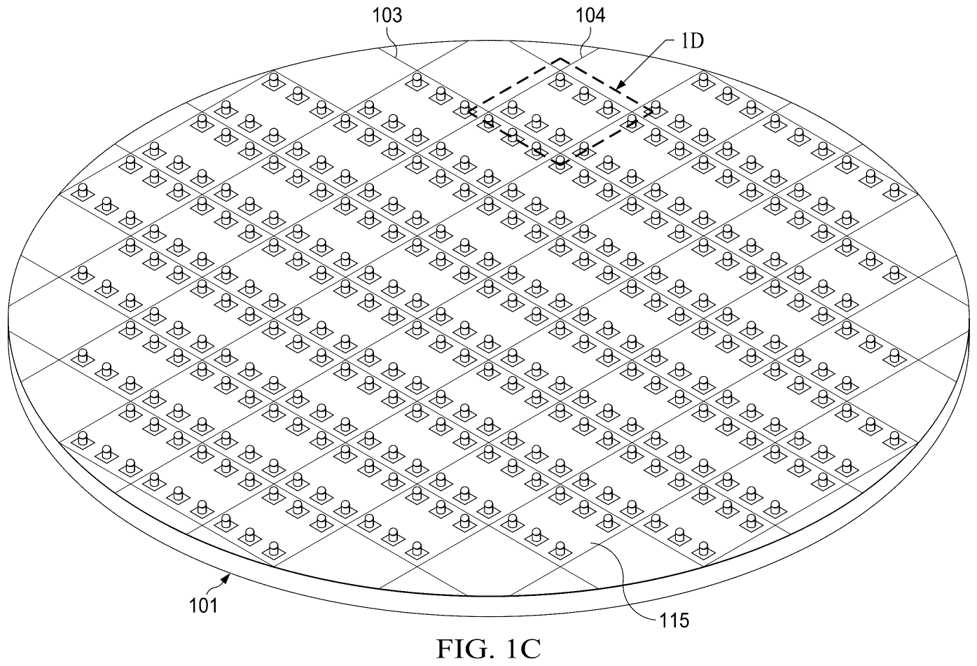

In FIG. 1A, semiconductor wafer 101 is shown with an array of semiconductor dies 105 arranged in rows and columns. The semiconductor dies 105 can be formed using manufacturing processes in a semiconductor manufacturing facility, the processes including ion implantation for carrier doping, anneals, oxidation, dielectric and conductor deposition, photolithography, pattern, etch, chemical mechanical polishing (CMP), electroplating, via formation and other processes for making semiconductor devices. Devices (not shown for clarity) are formed on a device side surface of the semiconductor dies. Scribe lanes 103 and 104, which are perpendicular to one another, and which run in parallel groups across the semiconductor wafer 101, separate the rows and columns of the completed semiconductor dies 105, and provide areas for dicing the wafer to separate the semiconductor dies 105 from one another.

FIG. 1B illustrates in a projection view a single semiconductor die 105 from the semiconductor wafer 101 in FIG. 1A, with bond pads 102, which are conductive pads that are electrically coupled to devices (the devices are not shown for simplicity of illustration) formed in the semiconductor dies 105. The semiconductor dies 105 can be separated from semiconductor wafer 101 by wafer dicing and are said to be “singulated” from one another, using the scribe lanes 103, 104 (see FIG. 1A).

In an example process useful with the arrangements, plasma dicing is used to singulate the dies 105 from the semiconductor wafer 101. Mechanical saw dicing or laser dicing can also be used. However, the minimum width of the scribe lanes needed for plasma dicing is substantially less than the minimum scribe lane widths required for either laser dicing or mechanical saw dicing, increasing the number of semiconductors dies that can be formed on a single semiconductor wafer, and increasing yields, which lowers unit costs.

The semiconductor die 105 of FIG. 1B is shown with bond pads 102 ready for wire bonding. The bond pads 102 are prepared to be electrically connected to conductive leads of a package substrate unit by forming wire bonds using bond wires that bond to and couple the bond pads 102 to conductive portions of leads of a package substrate, such as a leadframe.

FIGS. 1C-1D illustrate a semiconductor wafer and semiconductor die arranged for flip chip mounting to a package substrate using conductive post connects, such as copper pillar bumps. FIG. 1C illustrates semiconductor wafer 101 with scribe lanes 103 and 104 after a wafer bumping process places conductive post connects on the semiconductor dies 115. FIG. 1D illustrates a single semiconductor die 115 of FIG. 1C, with the conductive posts 114 on bond pads 112, and solder bumps 116 on the distal ends of the conductive posts. In an example process for forming the conductive post connects on the semiconductor dies, a seed layer is deposited over the surface of the wafer 101 including over the bond pads. Photoresist is used to pattern a mask over the wafer, and patterning is used to expose the seed layer in the bond pad areas. Electroless plating or electroplating can be used to form the conductive posts 114, which can be copper pillars, for example, with a proximal end on and coupled to the bond pads and a distal end extending away from the bond pads. In one example solder deposition process, solder balls can be dropped onto the distal ends of the conductive posts and in a thermal reflow process, the solder balls are used to form solder bumps 116 by melting the solder balls. The conductive posts and solder bumps can form copper pillar bumps. Gold conductive pillars can be formed as an alternative. After wafer dicing, the semiconductor die 115 can be mounted to conductive leads on a package substrate (such as a leadframe) by flip chip mounting, and using the solder bumps in a thermal reflow process, solder joints can be formed between the solder bumps and the leads of the package substrate to physically attach and electrically couple the semiconductor die 115 to a package substrate.

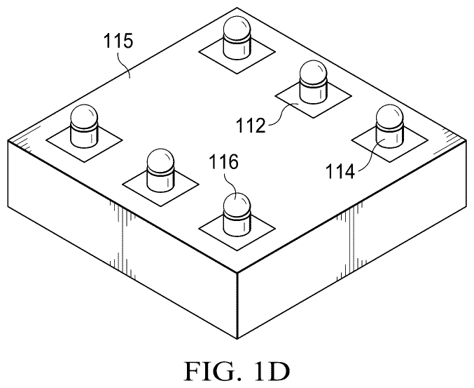

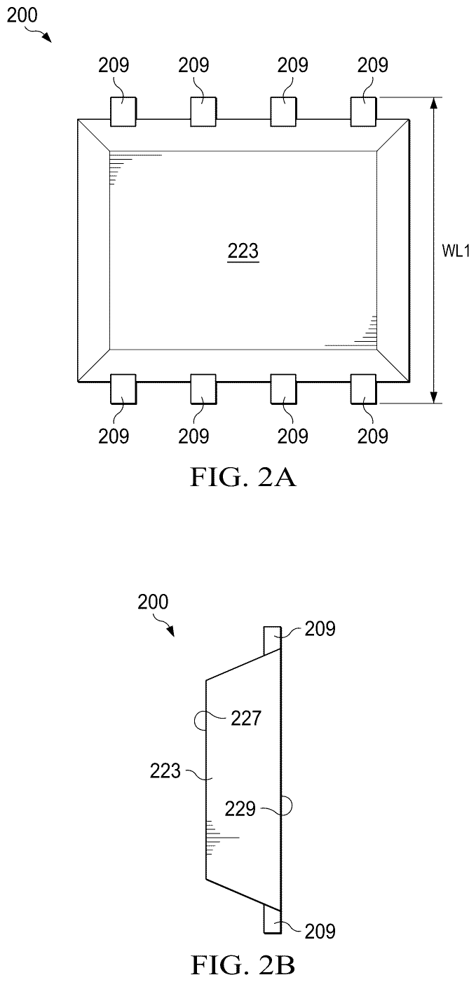

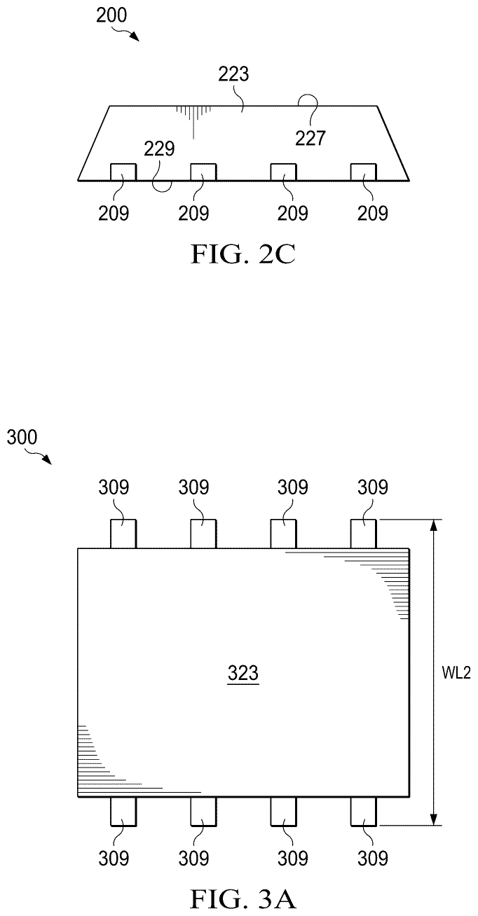

FIGS. 2A-2C illustrate, in a plan view, and end view, and side view, respectively, a semiconductor device package 200 that can be used in an example arrangement. In FIG. 2A, semiconductor device package 200 is shown in a plan view from a top side surface. Mold compound 223 forms a package body that covers and protects at least one semiconductor die (not shown in FIGS. 2A-2C) and the electrical connections from the semiconductor die to the leads. In the illustrated example, leads 209 are stub leads that extend outwards from two opposing sides of the package body formed by mold compound 223. The total width of the leads measured from tip-to-tip of the leads on opposite sides is labeled “WL1.” In an example the total width WL1 is about 6 millimeters, about the same as for standard small outline semiconductor device package having 8 leads. The use of the standard tip-to-tip width WL1 for the semiconductor device package 200 advantageously allows certain semiconductor device packages of the arrangements to be mounted on a board manufactured with an SOIC footprint for a prior semiconductor device package, without the need to modify the board layout. In contrast to conventional small outline semiconductor device packages such as SOIC packages, the stub lead packages of the arrangements have leads that are coplanar with the board side surface of the molded package body, and the entire board side of the lead is available to contact conductive land pads on the board and is arranged for solder, providing increased area for the solder joints (when compared to a gull wing shaped lead for the conventional SOIC package), and the stub leads also have increased area for solder wetting when compared to the terminals of a QFN package, (which has “no lead” terminals that are coextensive with the molded body of the QFN package.) Note that while the illustrated example has a width WL1 that is compatible with existing SOIC land patterns already on boards, in an alternative arrangement, the semiconductor device package 200 could have a smaller width, such as 4 mm or less, to increase integration and reduce board area. In these example arrangements, the land patterns would be new patterns on board designs, changed to correspond to the new semiconductor device package widths.

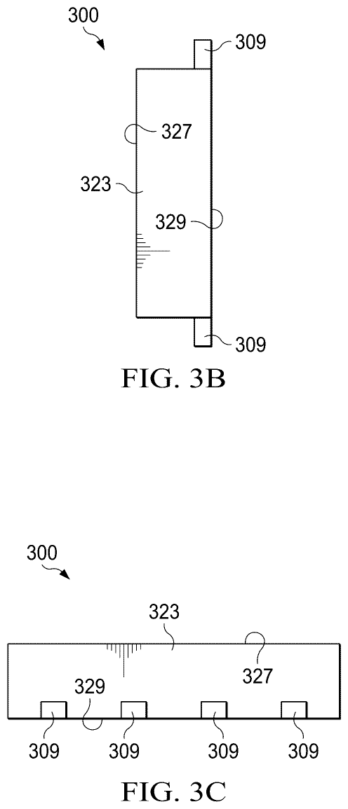

FIGS. 2B and 2C illustrate the semiconductor device package 200 in an end view (FIG. 2B) and a side view (FIG. 2C) with a top side surface 227 and an opposing board side surface 229. The example semiconductor device package 200 has eight leads arranged as four leads on two opposing sides, however in other alternative arrangement a semiconductor device package of the arrangements can have more or fewer leads, for example sixteen leads, eighteen leads, twelve leads, ten leads, etc. The semiconductor device package 200 has a body formed from the mold compound 223, with a top side surface 227, a board side surface 229, and having two opposing sides with leads 209 extending from the sides and having two opposing ends. The sides of the semiconductor device package 200 are shown with upward slanting shapes, which is one example of the shapes that can be formed for the semiconductor device package 200. As shown in FIGS. 3A-3C and described below, vertical shaped sides can be used, where the sides are approximately 90 degrees with respect to the bottom surface of the semiconductor device package, which in a normal orientation can be a horizontal surface.

FIGS. 3A-3C illustrate, in a plan view, and end view, and side view, respectively, a semiconductor device package 300 in an alternative example arrangement. In FIG. 3A, semiconductor device package 300 is shown in a plan view looking from the top side. Mold compound 323 forms a package body that covers and protects at least one semiconductor die (not shown in FIGS. 3A-3C) and the electrical connections from the semiconductor die to conductive leads of a package substrate, such as a leadframe. In this illustrated example, the leads 309 are stub leads that extend from the package body formed by mold compound 323, and the total package width measured from tip-to-tip of the leads 309 is labeled “WL2”. In an example the width WL2 is about 4.6 millimeters, less than the lead width WL1 for the alternative arrangement for semiconductor device package 200 shown in FIGS. 2A-2C. While the example semiconductor device package 300 has lead spacings arranged so that it can be mounted to the same board footprint as a standard SOIC semiconductor device package also having eight leads, the semiconductor device package 300 of the arrangements is smaller than that of semiconductor device package 200. The use of the smaller total package width WL2 in the arrangement shown in FIGS. 3A-3C allows an additional increased number of units per strip to be formed in a process for mounting the semiconductor dies and packaging the devices, as is further described below.

In the example illustrated in FIGS. 3A-3C, the semiconductor device package has opposing sides with the leads 309 extending from the mold compound 323 and away from the sides of the semiconductor device package 300, and opposite ends without leads. In the example shown in FIGS. 3A-3C, the sides and ends are shaped to be vertical (relative to the board side or the top surface of the semiconductor device package), in contrast to the upward slanting sides and ends of the semiconductor device package 200 shown in FIGS. 2A-2C. The sides are vertical meaning the sides are at an angle of approximately 90 degrees with respect to the board side or bottom surface of the semiconductor device package, which in a typical orientation can be a horizontal surface.

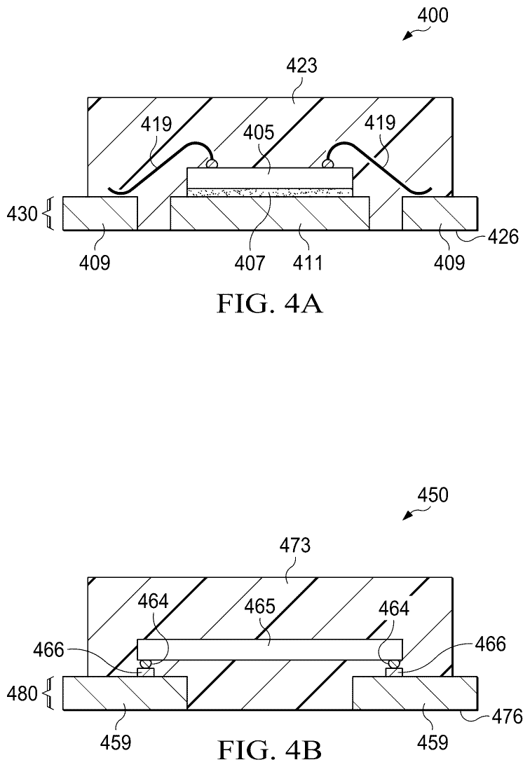

FIGS. 4A-4B illustrate, in cross-sectional views, a wire bonded semiconductor device package of an example arrangement including the stub leads, and a flip chip semiconductor device package of another example arrangement including the stub leads. In FIG. 4A, a semiconductor die 405, similar to semiconductor die 105 in FIG. 1B, is shown mounted to a package substrate 430 (in the illustrated example, a leadframe is used as the package substrate) by a die attach material 407. The semiconductor die 405 in FIG. 4A is mounted oriented “face up” with a backside surface mounted to a die pad of the package substrate 430 by the die attach material 407. The die pad is positioned in a die mount area in the center of the package substrate 430. In a useful example, a non-conductive die attach film (NCDAF) can be used for die attach material 407 to mount the semiconductor die 405 to the package substrate. In an alternative example, a conductive die attach film (CDAF) can be used for die attach material 407. Further alternatives for die attach material 407 include use of a die attach epoxy or paste that is deposited on the package substrate and then used to mount the semiconductor die 405 to the die pad. An exposed surface of the die pad on the board side surface of the semiconductor device package 400 forms a thermal pad 411. Thermal pad 411 is thermally coupled to the semiconductor die 405 and can be used to transfer thermal energy away from the semiconductor device package 400. For example, the thermal pad 411 can be thermally coupled to a thermal pad on a system board to conduct heat away from the semiconductor die 405.

Mold compound 423 in FIG. 4A covers the semiconductor die 405, the wire bonds 419, and portions of the package substrate 430; in this example a leadframe is used. Stub leads 409 are shown extending from mold compound 423 on opposite sides of the mold compound 423 and having an exposed bottom surface that is coplanar with the board side surface 426 of the semiconductor device package 400. The stub leads 409 are arranged for solder mounting to a board or module using surface mount technology (“SMT”) to mount the bottom surfaces of the stub leads 409 to conductive lands on a board or module (not shown) that are patterned to receive the semiconductor device package 400.

The semiconductor die 405 has bond pads (not shown in FIG. 4A for clarity, see bond pad 102 in FIG. 1B, for example) that are coupled to the stub leads 409 by wire bonds 419. In an example wire bonding process that can be used with the arrangements, a wire bonder tool is used to form the wire bonds. A capillary formed of a hard material such as a ceramic has a supply of bond wire that feeds through a central opening in the capillary. Copper, palladium coated copper (PCC), gold, silver, aluminum, and other conductive bond wire can be used. Recently copper and PCC bond wire are increasingly used. When copper or PCC bond wire is used, the wire bonder tool may be arranged to form an anoxic environment during wire bonding, to prevent rapid oxidation of the copper bond wires, as the wire bonding is performed at an elevated temperature, which accelerates oxidation and tarnish. Removing oxygen from the environment reduces oxidation.

In a wire bonding cycle that is useful in forming an arrangement, the process begins with a bond wire extending from a central opening in a capillary. A flame or electronic arc is used to form a molten ball at the exposed end of the bond wire. The capillary is then used to form a ball bond on a bond pad on a semiconductor die. In a thermosonic wire bonding process, ultrasonic energy, thermal energy, and mechanical pressure are used to form a ball bond between the ball on the bond wire and the bond pad. Sonic energy is applied to the capillary while it simultaneously pushes the ball onto the bond pad, and the bonding process is done at an elevated temperature, forming a ball bond. Once the ball bond is formed, the capillary moves away from the ball bond while the bond wire extends from the capillary. By using clamps mounted with the capillary to hold and shape the bond wire as it extends, an arc shape that keeps the bond wire above the semiconductor die and away from the edge of the semiconductor die can be formed. The capillary extends the bond wire to a position over a conductive lead where a bond connection is to be made. The capillary pushes the bond wire onto the lead and again using thermosonic energy, forms a “stitch” bond on the lead surface between the bond wire and the lead. After the stitch bond is formed, the capillary moves a short distance away from the lead and the bond wire is cut or broken, leaving a short tail on the stitch bond. The new free end of the bond wire is then available to start a new bonding cycle, which is repeated for the next wire bond. This type of wire bonding is referred to as a “ball and stitch” wire bonding process.

Wire bonding is fully automated and rapid, and many wire bonds can be formed each second in an automated wire bonding tool. Many semiconductor dies can be mounted to a package substrate strip (such as a leadframe strip) using die attach material, and then the wire bonder can form the needed wire bonds for all the semiconductor dies on the strip in a rapid sequence. Molding can then be used to form the body of the semiconductor device packages, as is further described below.

FIG. 4B illustrates, in another cross section, an alternative semiconductor device package 450 with stub leads 459, in this additional arrangement flip chip mounting is used. In FIG. 4B, a semiconductor die 465, similar to semiconductor die 115 in FIG. 1D, is shown mounted to a package substrate 480 using flip chip mounting. Conductive post connects 464 extend from bond pads (not shown for clarity) on the device side surface of the semiconductor die 465 to the internal ends of leads 459, which are positioned in a die mounting area for the device. Solder joints 466 are formed by a thermal reflow of the solder bumps on the distal ends of the conductive post connects. In the flip chip arrangements, the bond pads and the device side surface of the semiconductor die 465 face the board side surface of the semiconductor device package 450, in contrast to the “face up” orientation of the wire bonded semiconductor die 405 in the semiconductor device package 400 in FIG. 4A. A mold compound 473 then covers the semiconductor die 465, the conductive post connects 464 and the solder joints 466, and a portion of the package substrate 480, in this example a leadframe is used. Semiconductor device package 450 can be referred to as a “flip chip on lead” or “FCOL” type semiconductor device package. Leads 459 are stub leads of the arrangements, and in contrast to a conventional QFN package, for example, the stub leads 459 extend from the mold compound 473 on two opposing sides and away from the package body formed by mold compound 473. The stub leads 459 have exposed bottom surfaces for solder mounting that are coplanar with the board side surface 476 of the semiconductor device package 450. Because the stub leads of the semiconductor device packages of the arrangements have additional area for solder wetting (when compared to terminals of a conventional QFN package), the BLR for the stub lead semiconductor device packages of the arrangements is increased (when compared to a QFN package with the same number of terminals.)

The semiconductor device package 450 does not have a thermal pad (see thermal pad 411 in FIG. 4A) exposed from the mold compound 473, in contrast to the wire bonded semiconductor device package 400 of FIG. 4A, which includes an exposed thermal pad. A heat sink or fin can be mounted to the top side of the semiconductor device package 450 to improve thermal dissipation for semiconductor dies that require additional thermal compensation.

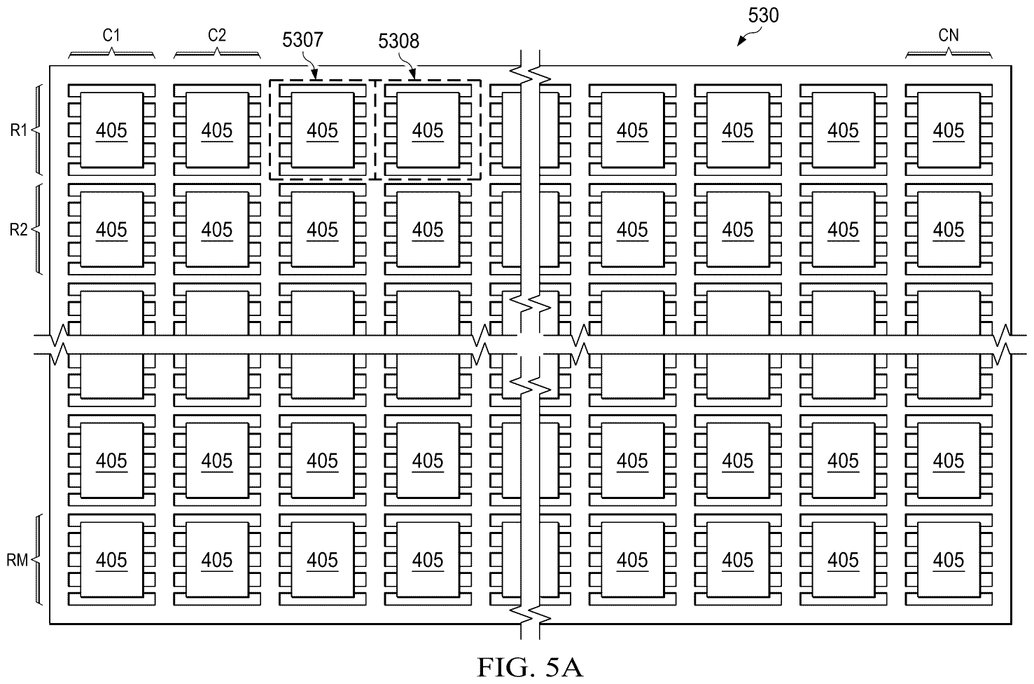

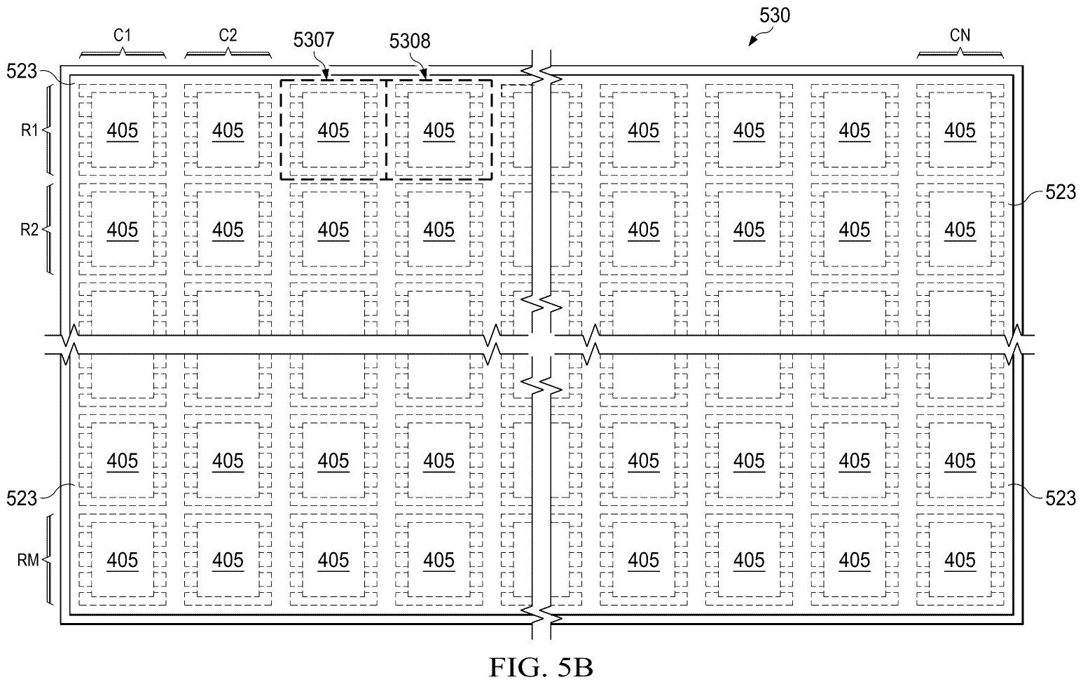

In the arrangements, a method for producing the stub lead semiconductor device packages includes a panel molding process. FIGS. 5A-5B illustrate, in a plan view, a package substrate strip that is arranged for use in the panel molding process (FIG, 5A) and a plan view the package substrate strip of FIG. 5A after transfer molding forms a molded panel for use in forming the arrangements.

In FIG. 5A, package substrate strip 530 has units such as 5307, 5308 arranged in M rows labeled “R1” to “RM” and N columns labeled “C1” to “CM”, where M and N are integers. In the illustrated example, there are 16 rows and 42 columns, for a units per strip or “UPS” of 16×42=672. This example UPS number is the number of packaged units obtained for forming the 6 mm wide semiconductor device packages of FIGS. 2A-2C. The use of the stub leads in the device units used in the arrangements allows for narrower saw streets (when compared to the saw street widths needed for a corresponding SOIC device package), the use of the arrangements with 16 rows and 42 columns yields 7% more devices for a package substrate strip of width 90 millimeters and of a length 270 millimeters, (when compared to a same sized strip used with the spacing for the prior approach SOIC devices that yields 15 rows×42 columns=630 UPS). The yield advantage of the example arrangements accrues even when the package substrate units used to form the arrangements is arranged on a non-interdigitated strip with device units in adjacent columns having stub leads that are aligned to one another, even while the unit strip used for the UPS comparison for the SOIC devices is a high density interdigitated leadframe, with leads from adjacent columns of devices staggered so the leads can extend in an interdigitated and staggered fashion. Interdigitated leadframes can increase the density of devices, but also increase costs due to the additional complexity in manufacturing. Use of the arrangements increases UPS by use of the stub leads of the arrangements, even in non-interdigitated unit strips, further reducing costs while yet increasing yields.

If the available area used for devices on the package substrate strip 530 is increased slightly to 100 millimeters×300 millimeters, for example by using more of the edge areas for mounting devices, the UPS can be increased further by having 17 rows (M=17) and 49 columns (N=49), the UPS can then be 17×47 =799, an increase of 27% over the prior approach for forming SOIC devices.

If package substrate strip 530 is arranged for the narrower stub lead semiconductor device packages 300 of the arrangement shown in FIGS. 3A-3C, for example, with a total package width of about 4.6 millimeters, use of the arrangements can still further increase the yields. In an example with a useful strip area of 90 millimeters×270 millimeters, the UPS achieved can be 16 rows×50 columns, or 800 devices. If the area used on the package substrate strip for forming devices is increased slightly to 100 millimeters×300 millimeters, the UPS achieved can be 1020, using 17 rows×60 columns. The example stub lead semiconductor device package 300 of FIGS. 3A-3C has shorter stub leads than the stub lead semiconductor device package 200 of FIGS. 2A-2C but has an additional yield advantage in an increased number of UPS.

FIG. 5B illustrates the package substrate strip 530 after a molding process. A mold compound 523 is formed as a continuous panel of mold compound extending over the entire device side surface of the package substrate strip 530. Using a panel molding process eliminates either unit molds that surround each device package, or block molds that are arranged to form mold compound in columns of molded devices. Use of panel molding in forming the arrangements has several advantages. The panel mold is semiconductor device agnostic, meaning that even producing different semiconductor device packages, such as having more or fewer leads, the mold tool does not need to be modified to produce the differing devices. No mold redesign or modification is needed if the semiconductor device package changes, or to produce different semiconductor device packages. After molding, the package substrate strip 530 and the panel of mold compound 523 are sawed apart using saw streets along rows and columns between the units to form individual semiconductor device packages, as is further described below.

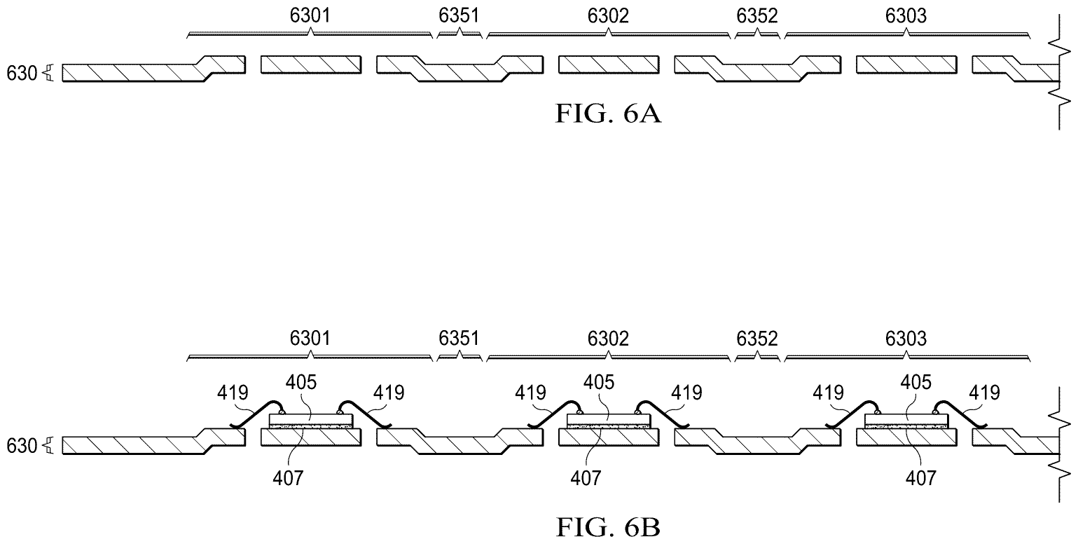

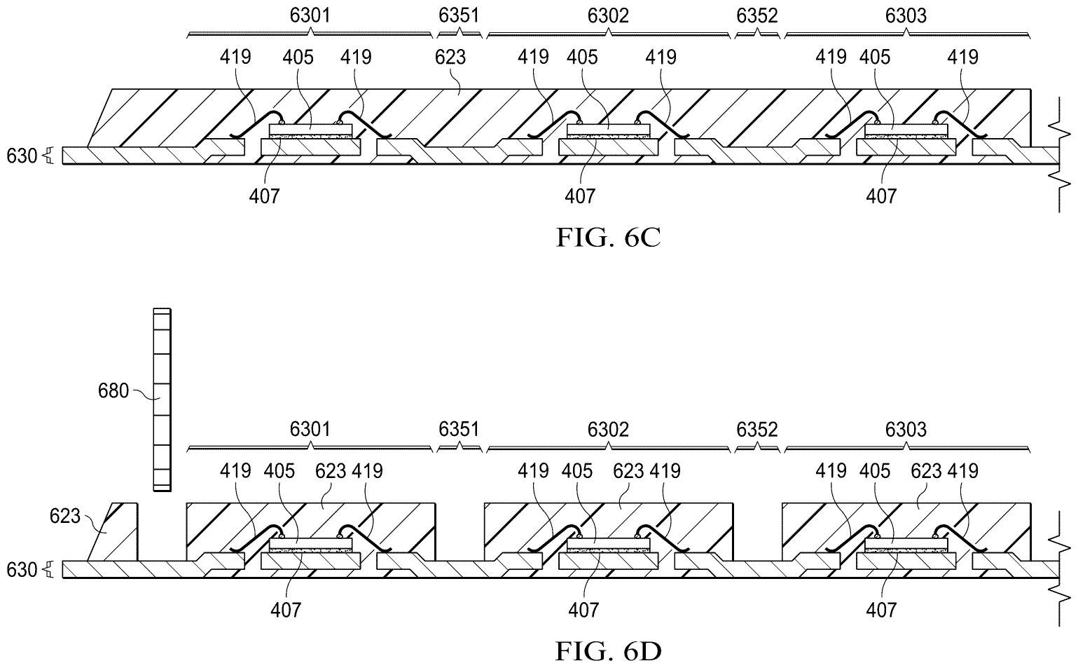

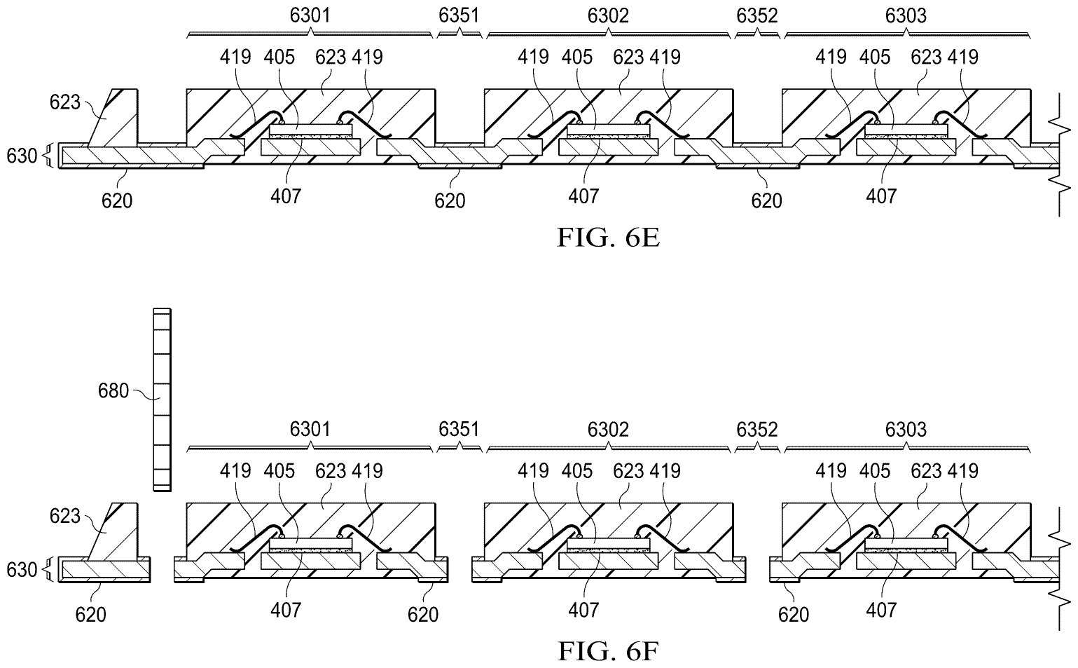

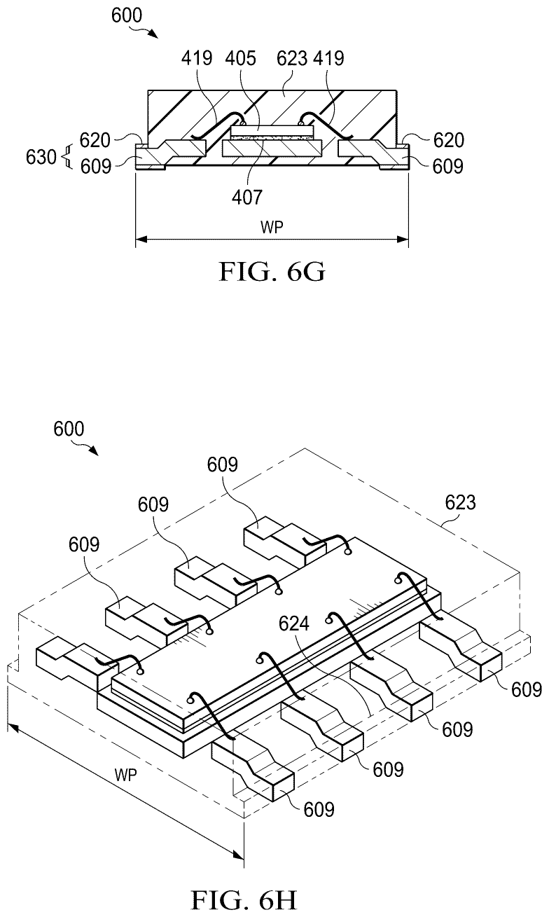

FIGS. 6A-6G illustrate, in a series of cross-sectional views, selected steps for forming semiconductor device packages of the arrangements with stub leads.

In FIG. 6A, the cross-sectional view illustrates a portion of a package substrate strip 630, which is similar to the package substrate strip 530 in FIG. 5A. Strip 630 includes package units such as 6301, 6302, 6303 arranged in rows and columns. The views of FIGS. 6A-6F are taken along a single row of package units. Saw streets 6351, 6352 are formed on the package substrate strip 630 between columns of package units. The package substrate strip 630 extends beyond the portion illustrated in FIG. 6A as indicated by the broken line at the right-hand side of the figure. The units 6301, 6303, 6305 in FIG. 6A are formed using “upset” leads, meaning that as the leads extend from outside a package boundary into the device packages, the leads have an angled portion that places the die pads on a different plane than the leads, at a higher position (in a cross-sectional view). The device units with the upset leads include a die pad in a first plane arranged above a second plane that is parallel to the board side surface of the leads when viewed in a cross-section. Use of upset leads has advantages in making wire bonding connections easier, and allows more flexibility in bond pad positions on the semiconductor dies, so that multiple different semiconductor dies can be used with the same package substrate design by extending bond wires over the leads in different patterns to electrically connect the bond pads to the appropriate leads. Note that a semiconductor device package formed using upset leads such as the package substrate strip 630 will not have an exposed thermal pad, for an alternative arrangement where an exposed thermal pad is needed, a planar strip can be used (see for example FIG. 4A, semiconductor device package 400 has a thermal pad 411.)

FIG. 6B illustrates in another cross-sectional view the elements shown in FIG. 6A after additional processing. In FIG. 6B, semiconductor dies 405 are shown mounted in a face up orientation to die pads of the device units 6301, 6302, and 6303 by die attach material 407. The semiconductor dies 405 can be mounted using a non-conductive die attach film, a conductive die attach film, or a die attach epoxy or paste for die attach material 407. Wire bonds 419 are shown coupling the semiconductor dies 405 to leads of the device units 6301, 6302, 6303 of the package substrate strip 630.

FIG. 6C illustrates in another cross-sectional view the elements shown in FIG. 6B after additional processing. In FIG. 6C, mold compound 623 is shown formed in a panel molding process to cover the device side surface of the package substrate strip 630 in a continuous panel of mold compound. In a process that is useful with the arrangements, a transfer molding process can be used. In the transfer molding process, mold compound that is a solid or a powder at room temperature is introduced into a mold tool. The mold compound can be, for example, epoxy resin mold compound (“EMC”) conventionally used in semiconductor packaging. The mold compound can include filler particles that add strength and increase thermal conductivity of the finished semiconductor device package. After heating the mold compound to a liquid state, pressure is used to force the liquid mold compound into a mold where the package substrate strip 630 is positioned, along with the semiconductor dies and wire bonds for each device unit in the package substrate strip. After the mold is filled with liquid mold compound that surrounds the semiconductor dies, the wire bonds, and portions of the leads, the mold compound is subsequently cured. Since the mold compound is a thermoset material, it forms a solid package body for the semiconductor device packages. In the process used to form the arrangements, a panel mold is used and the device side surface of the package substrate strip 630 is covered in a continuous panel of solid mold compound 623.

FIG. 6D illustrates in another cross-sectional view the elements shown in FIG. 6C after additional processing. In FIG. 6D, a first mechanical sawing operation is shown removing mold compound 623 from scribe lanes such as 6351, 6352 in a partial cut from a device side of the package substrate strip 630. The partial cut forms trenches along scribe lanes extending in between columns of the device units such as 6301, 6302, 6303, and exposes the top surface of the leads and the package substrate strip between the packaged semiconductor devices. To make the partial cuts, a mechanical rotating blade traverses the scribe lanes such as 6351, 6352 between columns of semiconductor devices and cuts through the mold compound 623 and exposes the top surface of the leads of the package substrate strip (including the top surface of the stub leads) between the columns of device units. Because in a cross sectional view the openings appear as trenches, this operation can be referred to as a “ditch cutting” operation, The package substrate strip 630 remains intact, and supports the semiconductor dies 405 for additional processing. The partial cutting operation of FIG. 6D defines the vertical sides of the semiconductor device packages.

FIG. 6E illustrates in another cross-sectional view the elements shown in FIG. 6D after additional processing. In FIG. 6E, the package substrate strip 630 is processed in a “post-mold” plating process. In an example process that is useful with the arrangements, a tin layer plating 620 is plated onto the exposed surfaces of the leads. The tin plating provides an improved surface for soldering operations in an SMT process for mounting the semiconductor device packages to a board. Alternative materials that can be plated include nickel, gold, palladium, and silver. The plating process is performed while the package substrate strip 630 remains intact and supports the semiconductor dies 405 and the wire bonds 619. Because mold compound 623 is applied to the devices before this plating step, the plating step can be referred to as a “post-mold” plating. The plating process is performed after the partial cuts (see FIG. 6D described above) expose the leads in the sawing operation of FIG. 6D so that the upper surfaces of the stub leads are exposed for the plating.

FIG. 6F illustrates in another cross-sectional view the elements shown in FIG. 6E after additional processing. In FIG. 6F, package substrate strip 630 is shown in a second sawing process that performs singulation of the semiconductor device packages (6301, 6302 . . . ) from one another. The units 6301, 6302 and 6303 are cut apart by mechanical saw 680 now traversing the scribe lanes 6351, 6352 between the semiconductor device packages, the sawing operation now cutting through the package substrate strip 630 to form the ends of the stub leads extending from the sides of the mold compound 623, and separating the devices one from another along the columns. Although not shown in FIG. 6F, the mechanical saw 680 will also cut along scribe lanes between rows of the semiconductor device packages (see FIG. 5A, rows R1-RM for example). The cuts along the rows form the vertical ends of the semiconductor device packages by cutting through the mold compound 623 and through the package substrate strip 630 between the rows of semiconductor device packages, forming vertical ends for the semiconductor device packages.

FIG. 6G illustrates, in a cross-sectional view, a completed semiconductor device package 600 which can be one of the devices of FIG. 6F, now shown after singulation. In FIG. 6G, the semiconductor device package 600 has stub leads 609 shown extending from the package body formed by mold compound 423. The stub leads 609 in the illustrated example of FIG. 6G includes plating 620, however in an alternative approach the plating 620 can be omitted. The semiconductor device package 600 includes a semiconductor die 405, the die attach material 407, and the wire bonds 419 connecting the semiconductor die to the leads of the package substrate 630. In an example, the width “WP” from tip-to-tip of the leads 609 can be similar to the width of conventional SOIC packages, for example 6 mm. In an alternative example, the width WP of the semiconductor device package can be smaller, for example, 4.6 millimeters.

FIG. 6H illustrates, in a projection view, the semiconductor device package of FIG. 6G to show additional details. In FIG. 6H, the semiconductor device package 600 has mold compound 624 lying between the leads 609, because of the panel molding process described above. The first sawing operation cuts to, but not through, the leads 609, and exposes the top surface of the leads 609 between columns of device units, forming a trench. This trench leaves mold compound between the sides of the leads 609. The mold compound 623 forms the package body but after the sawing operations, the mold compound 624 may remain between the leads 609. In an example arrangement, the mold compound 624 is left between the leads and the semiconductor device package 600 is mounted to a system board by solder on the board side surface of the leads 609 which are exposed from the mold compound 624 on the board side surface.

FIG. 6I illustrates, in an additional projection view, an alternative arrangement semiconductor device package 610. In FIG. 6I, the stub leads 619 are exposed from mold compound 623, so that the mold compound 624 between the stub leads has been removed (compare FIG. 6H where the mold compound 624 between the leads remains). In an example process that is useful with the arrangements, a water jet deflash process is used after the sawing singulation process of FIG. 6F to remove the mold compound between the leads. When the leads 619 are mounted to a board, the solder can wet the board side surface of the leads 619 and some wetting of the sides of the leads 619 can occur. The width “WP” of the semiconductor device packages 600 and 610 can be, for example, 6 millimeters, corresponding to the width WL1 as shown in FIG. 2A, or can be about 4.6 millimeters, corresponding to width WL2 as shown in FIG. 3A. These widths are compatible with existing board land patterns for SOIC packages. Other package widths can be used to form additional alternative arrangements. Example ranges include from in a range from about 3 mm to about 7 mm, with the smaller widths increasing the UPS yield over larger package widths. If the package width becomes too small, some difficulty in surface mounting the devices can result, when small devices “float” during a surface mount technology soldering operation. Use of the example widths described above, 6 millimeters and 4.6 millimeters, results in semiconductor device packages with increased UPS that are also compatible with surface mounting to lands on system boards or modules patterned for existing small outline integrated circuit (SOIC) packages or small outline packages (SOP). These example arrangements allow the stub lead semiconductor device packages to replace conventional semiconductor device packages on existing boards, without need for modifying the boards, which further lowers costs for use of the arrangements.

The package widths advantageously obtained by use of the arrangements result in additional UPS (when compared to prior approach SOIC packages). The stub leads used in the arrangements can be made shorter than the gull wing shaped leads used in the prior approaches because the stub leads are not shaped and do not extend from the center of the mold compound that forms the body of the packaged devices. Instead, in the semiconductor device packages of the arrangements, the stub leads extend coplanar with the board side surface of the mold compound and advantageously, the stub leads do not require the “trim and form” steps used to shape and align the leads for a gull wing or other leaded package, such as an SOIC package. While two possible package widths are specifically described herein as example arrangements, if the semiconductor device packages are to be mounted to a new board design with custom land patterns, other, smaller package widths could be formed in alternative arrangements with a package width less than 4.6 millimeters, for example as small as 3 millimeters could be used. Smaller package widths can further increase the UPS number, further reducing per unit costs.

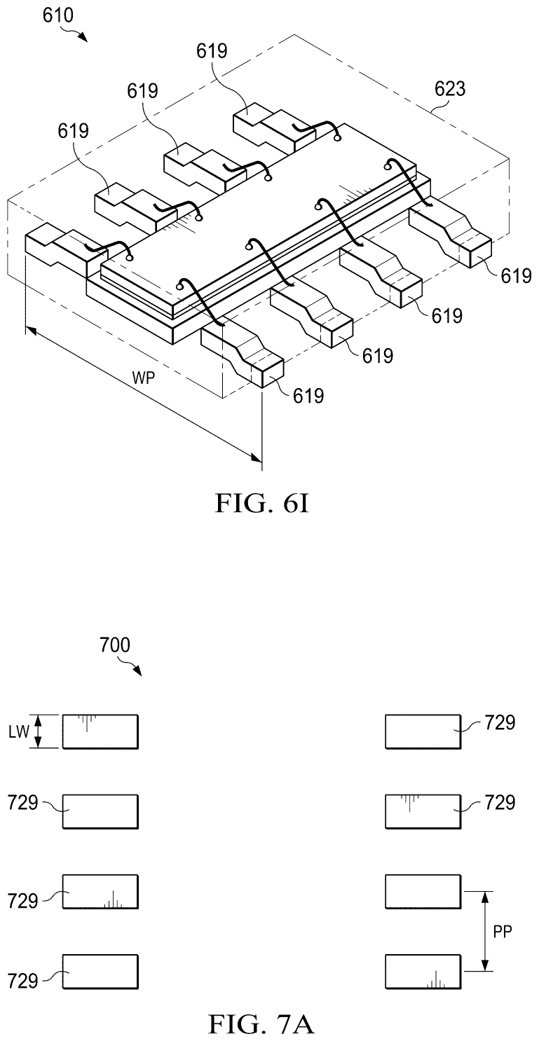

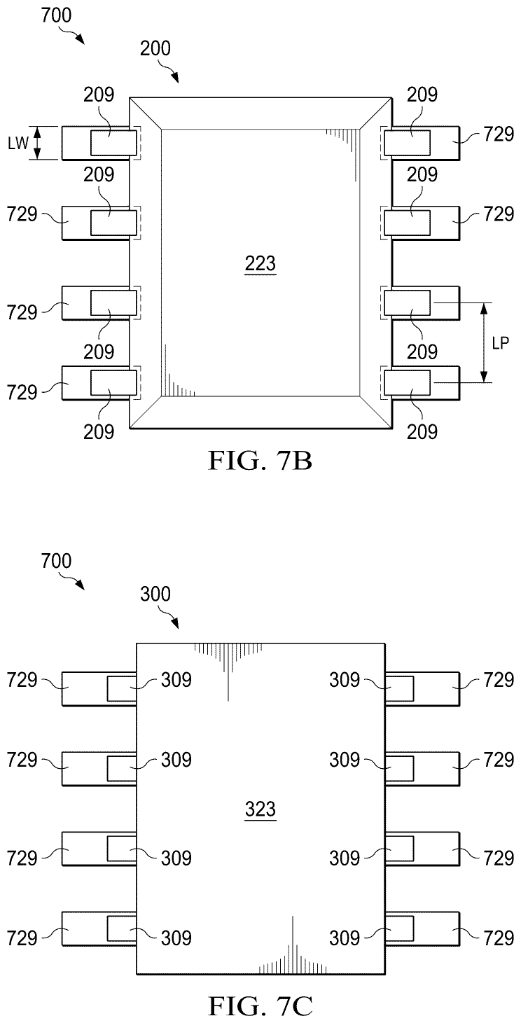

FIGS. 7A-7C illustrate, in plan views, a land pattern for a small outline semiconductor device package, a first arrangement shown overlying the land pattern to illustrate compatibility of the arrangement with the land pattern, and a second arrangement overlying the land pattern to illustrate compatibility of an alternative arrangement with the land pattern, respectively.

In FIG. 7A, in a plan view, a land pattern for a small outline semiconductor device package is shown. Land pattern 700 includes conductive lead pads 729, which are conductive traces for solder mounting a semiconductor device package. In this example shown in FIG. 7A, an eight-terminal small outline package land pattern is used. Small outline semiconductor device packages can have other numbers of terminals, for example 10, 14, 16, 18, 24, and more, and land patterns for each of these devices can be formed for solder mounting. Stub lead semiconductor device packages can be formed as additional alternative example arrangements having various numbers of leads, the stub lead semiconductor device packages of the arrangements can have lead widths that are compatible with existing board land patterns to advantageously allow the semiconductor device packages of the arrangements to replace prior semiconductor device packages without modification to the board patterns.

In FIG. 7A, the pad pitch “PP” from center to center can be, for example, a standard distance of 0.050 inches (1.27 millimeters). Other standard pitches are used for various land patterns for prior packages. The land width “LW” can be a standard width of about 0.028 inches (0.7112 millimeters). Other land widths can be used for various prior packages. In example arrangements, the stub lead semiconductor device packages can be made compatible with existing land patterns to allow the semiconductor device packages to be used with existing board designs.

FIG. 7B illustrates, in a plan view looking through the board towards the board side surface of a semiconductor device package 200 (or alternatively, 600), the semiconductor device package 200 placed on the land pattern 700 of FIG. 7A. FIG. 7B illustrates that the stub leads 209 are placed correctly on the land pattern 700, The leads 209 have a lead-to-lead pitch distance “LP”, taken center to center, which is the same as the pad pitch “PP” of FIG. 7A. The lead width “LW” can be less than the pad width “PW” in FIG. 7A, for example 0.02 inches (0.5 mm). The leads 209 are arranged to correspond to the width and pitch of the small outline device land pattern 700. Note that the length of the stub leads 209 does not extend to the end of the pads but overlies most of the pad. In the illustrated examples the lead pitch and lead widths are compatible with existing land patterns on boards for SOIC packages. In an alternative approach, new package designs using the stub lead semiconductor device packages of the arrangements can be formed, and land patterns on new board designs can be arranged to correspond to the new semiconductor device packages, to reduce board area, to reduce semiconductor device package sizes, to increase UPS, and to increase integration.

FIG. 7C illustrates, in another plan view, the stub lead semiconductor device package 300 (see FIG. 3A) with shorter stub leads (compared to the stub lead semiconductor device package 200, shown in FIG. 7B). The semiconductor device package 300 has stub leads 309 that extend from the mold compound 323 on two opposite sides of the semiconductor device package 300. The stub leads 309 of semiconductor device package 300 are shorter than the stub leads 209 of semiconductor device package 200. As shown in FIG. 7C, the semiconductor device package 300 is arranged so that the leads 309 correspond in lead pitch and lead width to the land pattern 700, so that the semiconductor device package 300 can be mounted to boards using a standard small outline package land pattern. Surface mounting of the semiconductor device package 200 with the longer stub leads may be easier than mounting of the semiconductor device package 300 with the shorter stub leads, however an advantage of the semiconductor device packages with shorter stub leads is increased yield, as described above, that is increased units per strip (UPS).

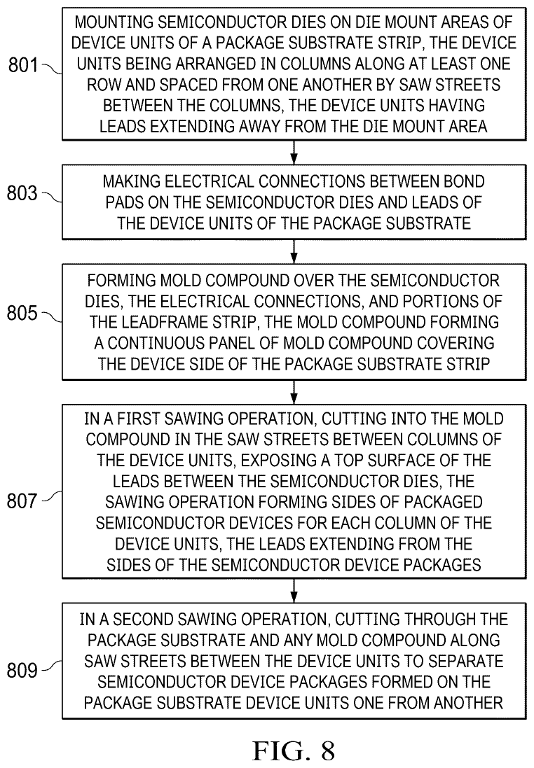

FIG. 8 illustrates, in a flow diagram, a method for forming a semiconductor device package of an arrangement. The method begins at step 801, by mounting semiconductor dies on die mount areas of units of a package substrate strip, the units being arranged in columns along at least one row and spaced from one another by saw streets between the columns, the units having leads extending away from the die mount area. (See, for example FIG. 6B, semiconductor dies 405 mounted to device units 6301, 6302, and 6303).

At step 803, the method continues by making electrical connections between bond pads on the semiconductor dies and leads of the package substrate. (See, for example, FIG. 6B, where wire bonds 619 couple the semiconductor dies to leads of the device units 6301, 6302, 6303.)

At step 805, the method continues by forming mold compound over the semiconductor dies, the electrical connections, and portions of the leads of the package substrate strip, the mold compound forming a continuous panel of mold compound covering the device side of the package substrate strip.

At step 807 the method continues by, in a first sawing operation, cutting into the mold compound in the saw streets between columns of the device units, exposing a top surface of the leads between the semiconductor dies, the sawing operation forming sides of packaged semiconductor devices for each column of the device units, the leads extending from the sides of the semiconductor device packages. (See, for example, FIG. 6D, where the sawblade 680 cuts partially into mold compound 623 from a device side).

At step 809, the method is completed by, in a second sawing operation, cutting through the package substrate strip along saw streets between the device units to separate semiconductor device packages one from another. (See, for example, FIG. 6F, where the rotating blade cuts through the package substrate strip between the semiconductor device packages, separating the devices from one another).

As described above, in some examples, an optional plating step is performed between the first and second sawing operations (see, for example, FIG. 6E, where plating 620 is deposited on the exposed leads.) Also, as described above, a water jet process can be performed after the second sawing operation to remove mold compound from the side surfaces of the exposed leads (see, for example, FIG. 6H with mold compound 624 between the leads, and FIG. 6I, showing the leads with mold compound 624 removed.)

Modifications and variations are contemplated and can be made in the described arrangements, and other alternative arrangements are possible that are within the scope of the claims.

What is claimed is:

1. A method, comprising:
mounting semiconductor dies on die mount areas of device units of a package substrate strip, the device units being arranged in columns along at least one row and spaced from one another by saw streets between the columns, the device units having leads arranged with ends proximate to the die mount areas and the leads extending to the saw streets;
making electrical connections between bond pads on the semiconductor dies and leads of the device units of the package substrate strip;
forming mold compound over the semiconductor dies, the electrical connections, and portions of the leads, wherein a continuous panel of the mold compound is formed covering the device side of the package substrate strip;
in a first sawing operation, cutting into the mold compound in the saw streets between columns of the device units, exposing a top surface of the leads between the semiconductor dies, the sawing operation forming sides of packaged semiconductor devices for each column of the device units, the leads extending from the sides of the semiconductor device packages; and
in a second sawing operation, cutting through the package substrate strip and the mold compound along saw streets between the device units to separate semiconductor device packages formed on the package substrate strip one from another;
wherein the semiconductor device packages have leads extending from two opposite sides of the mold compound for the semiconductor device packages, the leads having a board side surface that is coplanar with the board side surface of the semiconductor device packages, the leads having mold compound between the leads on opposing side surfaces of the leads.

2. The method of claim 1, wherein making electrical connections between bond pads on the semiconductor dies and leads of the device units further comprises:
forming wire bonds coupling bond pads on the semiconductor dies to leads of the device units, wherein the semiconductor dies are mounted on a die pad of the device units in the die mount area with the bond pads facing away from the die pads.

3. The method of claim 2, wherein the die pads of the device units have a board side surface exposed from the mold compound that form thermal pads for the semiconductor device packages.

4. The method of claim 1, wherein making electrical connections between bond pads on the semiconductor dies and leads of the device units further comprises:
flip chip mounting the semiconductor dies on the device units in the die mount areas, and forming solder joints using a thermal reflow process to melt solder of solder bumps formed on conductive post connects extending from the bond pads of the semiconductor dies while the solder bumps are positioned on the leads of the device units.

5. The method of claim 1, and further comprising:
prior to the second sawing operation, forming a plating on exposed portions of the leads of the device units.

6. The method of claim 1, and further comprising:
after the second sawing, performing a deflash process to remove mold compound from the side surfaces of the leads of the semiconductor device packages.

7. The method of claim 1, wherein the device units include upset leads with a die pad in a first plane arranged above a second plane that is parallel to the board side surface of the leads when viewed in a cross-section.

8. The method of claim 1, wherein the semiconductor device packages have a package width taken from tip-to-tip of tips of the leads on one side of the semiconductor device packages to tips of the leads on the opposite side of about 6 millimeters.

9. The method of claim 1, wherein the semiconductor device packages have a width taken from tip-to-tip from the leads on one side of the semiconductor device packages to the leads on the opposite side of about 4.6 millimeters.

10. The method of claim 1, wherein the leads of the semiconductor device packages have a lead-to-lead pitch distance of about 1.27 millimeters.

11. The method of claim 1, wherein the semiconductor device packages have a width taken from tip-to-tip of the tips of the leads on one side of the semiconductor device packages to the tips of the leads on the opposite side in a range of between 3 millimeters and 7 millimeters.

12. A semiconductor device package, comprising:
a semiconductor die mounted to a device side surface of a device unit of a package substrate, the device unit having leads extending from a die mount area;
electrical connections between bond pads on the semiconductor die and the leads of the device unit; and
mold compound covering the semiconductor die, the electrical connections, and portions of the leads, the mold compound forming the body of a semiconductor device package for the semiconductor die having a board side surface, and opposing top side surface, and sides between the board side surface and the top side surface;
wherein the leads extend outwards on two opposite sides from the body of the semiconductor device package formed by the mold compound and the leads have a board side surface that is coplanar with the board side surface of the mold compound.

13. The semiconductor device package of claim 12, wherein:
the die mount area further comprises a die pad in a central portion of the device unit spaced from internal ends of the leads; and
the semiconductor die is mounted to the die pad on the device side surface of the device unit with bond pads of the semiconductor die facing away from the device side surface.

14. The semiconductor device package of claim 13, wherein the electrical connections further comprise wire bonds formed between the bond pads on the semiconductor die and the leads of the device unit.

15. The semiconductor device package of claim 12, wherein mold compound is formed between the sides of the leads where the leads extend outwards from the body of the semiconductor device package, the leads having board side surfaces exposed from the mold compound and having top side surfaces exposed from the mold compound.

16. The semiconductor device package of claim 12, wherein the leads extend outwards from the body of the semiconductor device package and have a board side surface, a top side surface, and vertical sides between the board side surface and the top side surface that are free from mold compound.

17. The semiconductor device package of claim 12, wherein the semiconductor die is flip chip mounted to the die mount area of the device unit formed by the internal end of the leads, the semiconductor die mounted with bond pads facing the device side surface of the device unit and wherein the electrical connections are formed by solder joints between solder on conductive post connects extending from the bond pads of the semiconductor die.

18. The semiconductor device package of claim 12, wherein a package width measured from lead tip to lead tip taken from opposite sides of the semiconductor device package is about 6 millimeters.

19. The semiconductor device package of claim 12, wherein a package width measured from lead tip to lead tip taken from opposite sides of the semiconductor device package is about 4.6 millimeters.

20. The semiconductor device package of claim 12, wherein a package width measured from lead tip to lead tip taken from opposite sides of the semiconductor device package is in a range from 3 millimeters to 7 millimeters.

21. A method, comprising:
forming a strip of device units of a package substrate with a device side surface and an opposite board side surface, the strip comprising an array of device units arranged in columns along at least one row, the device units having leads on two sides extending from and coupled between the columns in saw streets between the columns, and having die pads in a die mount area spaced from internal ends of the leads;
mounting semiconductor dies to the die pads of the device units, the semiconductor dies having bond pads and mounted with the bond pads facing away from the device side surface of the device units;
forming wire bonds between the bond pads of the semiconductor dies and leads of the device units;
forming a layer of mold compound covering the device side surface of the package substrate strip in a continuous block of mold compound, the leads having a board side surface exposed from the mold compound;
in a first sawing operation, forming openings into the mold compound in the saw streets between the columns of device units to expose a top side surface of the leads, the first sawing operation forming opposing vertical sides of semiconductor device packages for each semiconductor die; and
in a second sawing operation, cutting through the layer of mold compound and the package substrate strip along the saw streets between the columns and sawing along additional saw streets between rows of the device units to separate the semiconductor device packages, the second sawing operation forming vertical sides at opposing ends of the semiconductor device packages, and the semiconductor device packages having leads extending on two opposite sides, the leads having a board side surface that is coplanar with the board side surface of the semiconductor device package.

22. The method of claim 21, and further comprising:
after the first sawing operation, and prior to the second sawing operation, performing a plating process to form a plating on the board side surface and on the top side surface of the leads extending from the semiconductor device packages.

23. The method of claim 21, and further comprising:
performing a deflash operation to remove the mold compound from between the sides of the leads where the leads extend from the body of the semiconductor device package formed by the mold compound.

24. The method of claim 23, wherein performing a deflash operation further comprises a water jet deflash operation.

25. The method of claim 21, wherein the semiconductor device packages have a width taken from the tips of the leads on one side of the semiconductor device packages to the tips of the leads on the opposite side in a range of between 3 millimeters and 7 millimeters.
